(19) United States
(12) Patent Application Publication
(10) Pub. No.: US 2022/0014400 A1
(43) Pub. Date: Jan. 13, 2022

(54) METHOD TO COMPENSATE FOR POST-TRAINING INSERTION LOSS VARIATION

(71) Applicant: Intel Corporation, Santa Clara, CA (US)

(72) Inventors: Yaniv HADAR, Yokneam Elite (IL); Golan PERRY, Haifa (IL); Kevan A. LILLIE, Chandler, AZ (US); Kenji HIRATA, Zapopan (MX)

(21) Appl. No.: 17/485,032

(22) Filed: Sep. 24, 2021

(51) Int. Cl. H04L 25/03

(52) U.S. Cl. CPC H04L 25/03057

(57) ABSTRACT

Methods and apparatus to compensate for post-training insertion loss variation. Receiver Physical Layer (PHY) circuitry for each receive lane in a link comprising a chain of equalizer components including a Variable Gain Amplifier (VGA). In conjunction with initial link training, the VGA gain is set based on an initial temperature. During link training, one or more of the equalizer components are adjusted to obtain link convergence, followed by transitioning to a “link up” phase under which data transmission and reception begin. While operating in the link up phase, one or more of the equalizer components are adjusted in response to changes in interconnect insertion loss to maintain operation of the link within a link margin. The method may be implemented in various types of links including but not limited to Ethernet, PCIe, CXL, and UPI links.

### BACKGROUND INFORMATION

Printed circuit board (PCB) materials exhibit temperature dependent characteristics, some of which result in greater signal attenuation at higher temperatures. The signal losses are also higher at higher data rates. Systems operating in wide temperature ranges, such as in outdoor environments can see PCB interconnect loss variation exceeding 6 dB at 25 Gbps signaling rates. In some implementations, such as Telecom, transceivers should be able to tolerate this variation error free, across the entire temperature range without requiring re-establishment or re-training of links over lengthy periods, such as several years.

In addition to PCB materials, other components along link signal paths may exhibit signal attenuation at higher temperature. For example, this may include cables and connectors.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a graph depicting insertion losses vs. signaling rates for a PCB at different temperatures;

FIG. 2 is a schematic diagram illustrating receiver equalization components implemented in a receiver PHY (Physical Layer) that are used to establish initial link equalization parameters and subsequently adjust the link signals to adapt to changes in the temperature;

FIG. 3 is a flowchart illustrating operations and logic for implementing an equalization convergence flow, according to one embodiment;

FIG. 4 is a schematic diagram of an SoC including an Ethernet multirate PHY, according to one embodiment;

FIGS. 5a and 5b respectively show plan and cross-section views of a compute platform including a link implemented using traces and vias in a PCB;

FIG. 6a is a diagram illustrating a first configuration under which a pair of link partners include an SoC coupled to an SFP+ module to which opposing ends of a cable are coupled, and wherein the link signal path includes segments in the PCBs and the cable;

FIG. 6b is a diagram illustrating a variation of the first link partner in which the link signal path includes a retimer;

FIG. 6c shows a link path configuration under which two platforms are coupled to a connector and the link path includes segments in the PCBs of each platform and the connector;

FIG. 7 is a schematic diagram illustrating a genericized PHY chip/block and associated Transmit (Tx) and Receive (Rx) circuitry, according to one embodiment; and

FIG. 8 is a schematic diagram of an exemplary implementation environment in which continuous adaptive equalization is implemented in a compute platform in a street cabinet located at the base of a cellular tower and exposed to ambient weather conditions.

### DETAILED DESCRIPTION

Embodiments of methods and apparatus to compensate for post-training insertion loss variation are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

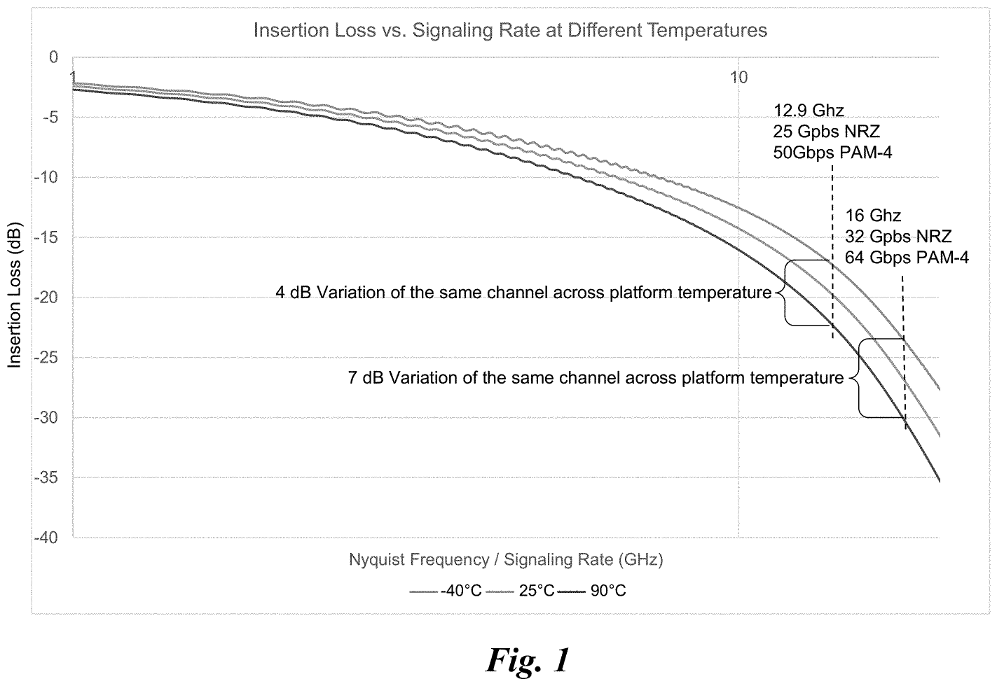

Insertion loss of high-speed serial interconnect on PCBs varies proportionally to the electrical signaling rate. Further, the insertion loss also varies proportionally with platform temperature. These variations depend on the PCB material selection. FIG. 1 shows a plot of these two affects. Observe that at a Nyquist frequency of 12.9 GHz (25 Gbps NRZ (non-return to zero) operation) that the same route on the PCB varies by 4 dB from −40 C to 85 C board temperature. A receiver should compensate for this increase or decrease in the attenuation of the system without causing additional bit errors or requiring the link to be re-established and trained at a new operating temperature.

For example, suppose the link is initially established at a platform temperature of 90 C and operates error free with a healthy margin. As time passes, the platform temperature may decline such that the insertion loss of the operating channel is reduced. The receiver is expected to operate error free with its initial solution when the interconnect is more lossy, and equally so sometime later when the interconnect is less lossy. The receiver applies additional attenuation to the incoming signal to compensate for the reduced system loss. It should apply this attenuation gradually over time and without causing any errors or dropping the link. Conversely, a link initially established at a low interconnect temperature should add additional gain to the link solution to compensate for the additional loss incurred as the interconnect temperatures increases.

In accordance with aspects of the embodiments disclosed herein the current temperature is incorporated as an indicator for the current interconnect insertion loss such that the receiver's convergence reserves additional adaptation capability for either post-training attenuation or gain if the link is established towards either temperature extreme. This approach reduces the need for the receiver to be capable of both additional attenuation and gain at any condition that it initially established the link, which would require additional operating margin in the design.

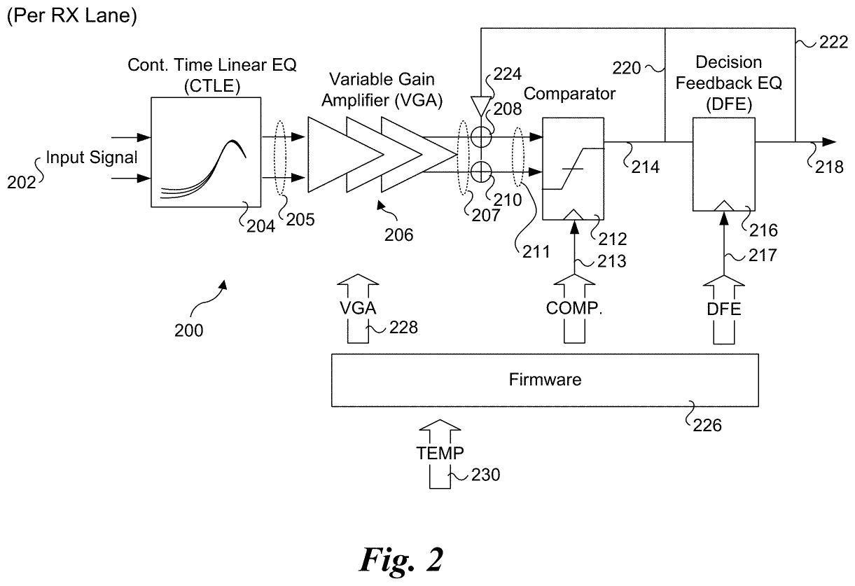

During initial adaptation of the link, the receiver trains its equalizers to maximize the link's margin at that operating condition. During this time, bit errors are allowed on the link and the receiver starts from an initial configuration and converges to a suitable solution by adapting each of its several equalizers. In one embodiment shown in FIG. 2, the receiver may use a Continuous Time Linear Equalizer (CTLE), a Variable Gain Amplifier (VGA) and a Decision Feedback Equalizer (DFE) to achieve a sufficient signal-to-noise ratio to operate error free. Under this novel methodology, the initial condition of the receiver's equalizers are programmed based on the device or platform temperature at the time the link is established. By programming these parameters based on temperature, the receiver's automatic adaptation mechanism will steer the overall convergence solution such that it will reserve enough of the right capability (additional gain or attenuation) for any future demands on the link solution that a changing environment might impose.

FIG. 2 shows receiver equalization components 200 implemented in a receiver PHY (Physical Layer) that are used to establish initial link equalization parameters and subsequently adjust the link signals to adapt to changes in the platform temperature. A pair of differential input signals 202 are fed into a CTLE 204, which performs a first signal equalizer adjustment and outputs a pair of differential signals 205 that are fed into a variable gain amplifier 206. The VGA 206 applies a variable gain to differential signals 205 and outputs gain-adjusted differential signals 207, which are provided as inputs to respective summing blocks 208 and 210, which in turn output differential signals 211 that are provided as inputs to a comparator 212.

Comparator 212 includes a threshold adjustment input 213 and performs a comparator threshold function to output a signal 214 that is feed into a DFE 216 including a DFE adjustment signal 217. DFE 216 then outputs an equalized signal 218. As further shown by feedback loops 220 and 222, signals 214 and 218 are fed back through an amplifier 224 and provided as second inputs to summing blocks 208 and 210.

FIG. 2 further shows firmware 226 that is executed on a processing element (not shown) and provides control/adjustment inputs 228 to VGA 206, threshold adjustment input 213, and DFE adjustment signal 217. Firmware 226 also receives one or more temperature inputs 230.

In one embodiment the receiver's firmware samples the current die temperature as a proxy for the platform temperature, assuming that the die temperature correlates to the platform temperature and the interconnect loss. In other embodiments, one or more temperature sensors may be used to measure the platform temperature (e.g., a temperature sensor on a PCB). Based on the current temperature, the firmware programs the VGA gain. When the temperature is below a certain threshold, the VGA gain is set to a low value. When the convergence logic of the receiver takes this into account, the other equalizers will converge on a link solution that accommodates this lower VGA gain. For example, the CTLE will select a higher gain solution for the overall link because while the VGA gain is initialized at a lower value, the requirements and the method for the link solution remain the same. Once the link solution is determined, the link-up state is established and the link transitions from the link training phase to the continuous adaptation phase during which data is transmitted over the link.

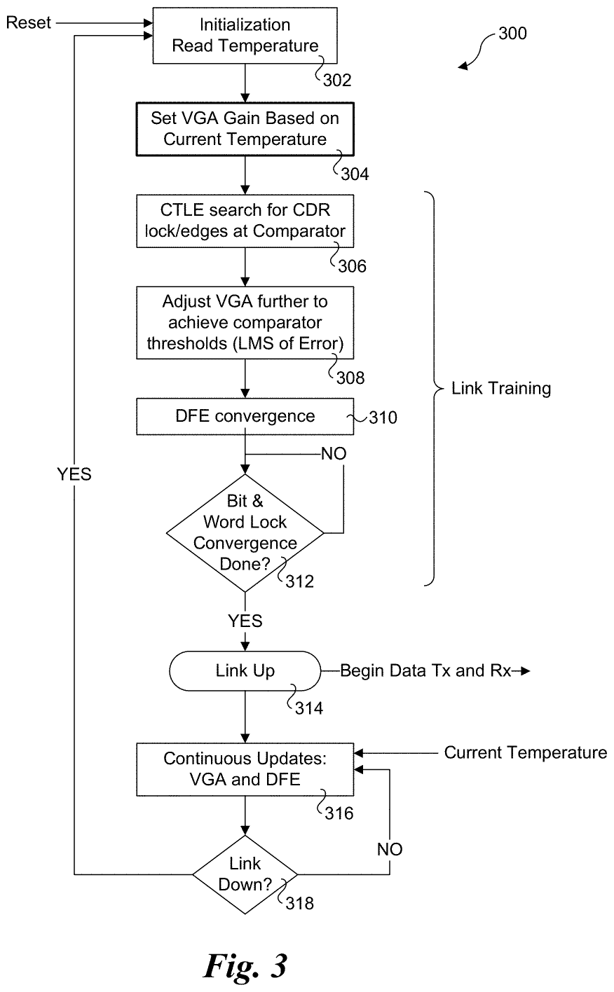

FIG. 3 shows a flowchart 300 illustrating operations and logic for implementing an equalization convergence flow, according to one embodiment. The flow begins with a reset signal received at a block 302 in which the initialization temperature is read. As described above, in one embodiment this is the SoC die temperature; optionally, one or more other temperature sensors may be used.

In a block 304, the firmware gain for VGA 206 is set based on the current temperature. In one embodiment the VGA gain is set using a table of preset gain vs. temperature values. In another embodiment, a gain vs. temperature function is used.

In a block 306, CTLE 204 is adjusted to search for CDR (Clock and Data Recovery) lock/edges at comparator 212. In a block 308, VGA 206 is adjusted further to achieve comparator thresholds (e.g., Least Mean Square (LMS) of error). In a block 310, DFE 216 is adjusted to achieve DFE convergence. As depicted by a decision block 312, DFE convergence is performed until bit and word lock convergences is completed. As further depicted, the operations in blocks 306, 308, 310, and decision block 312 are performed during link training.

Following link training, the flow enters a “Link Up” start block 314 and begins to transmit data over the link. As depicted in a block 316, the VGA gain and DFE are continuously updated based on changes to the current temperature. As further shown by a decision block 318, the link is monitored to ensure it is operating within the link margins. If a link margin is exceeded or otherwise a link failure is detected, decision block 318 determines the link is down (or otherwise should be reset) and the logic returns to block 302 to reinitialize the link.

During the continuous adaptation phase bit errors are not permitted. The receiver continues to adjust some of the equalizer coefficients that can be adjusted without causing errors. This includes the VGA. Since it was initially targeted to a low gain solution (in one example), the VGA has reserved additional gain capability to continuously and gradually adjust to any potential increase in channel loss in the system as the temperature rises.

Similarly, if the current die temperature is in the mid-range, between a low threshold and a high threshold, the VGA gain initial target will be for a mid-gain value, such that through continuous adaptation the gain can be increased or decreased (attenuates) compensating for any changes in the interconnect loss.

In this example the VGA gain initial target is programmed based on the temperature. If necessary, the CTLE solution could also be bounded to further preserve margin for future link changes.

It this example, setting the initial VGA gain based on temperature means that when the CTLE is initially adapted, the current VGA setting influences the convergence solution of the CTLE, and then once the CTLE is tuned appropriately further adaptation of the VGA is performed. The sequence of the adaptation of the individual equalization tools is important to this solution, in this example. Other sequences are also applicable and do not change the nature of the temperature dependent methodology.

### Example Implementations

As illustrated in the following figures, the continuous receiver adaptation approach may be used for different use cases and environments. Under one example use case, the approach is used to compensate for post-training insertion loss variation in signals transmitted via traces in a PCB. As an extension of this approach, the compensation may also apply to the full transmission route between two link partners, including PCB trace portions of the signal path in PCBs in the two link partners as well as the portion of the signal path comprising a cable or the link connected between the (link interfaces of the) link partners.

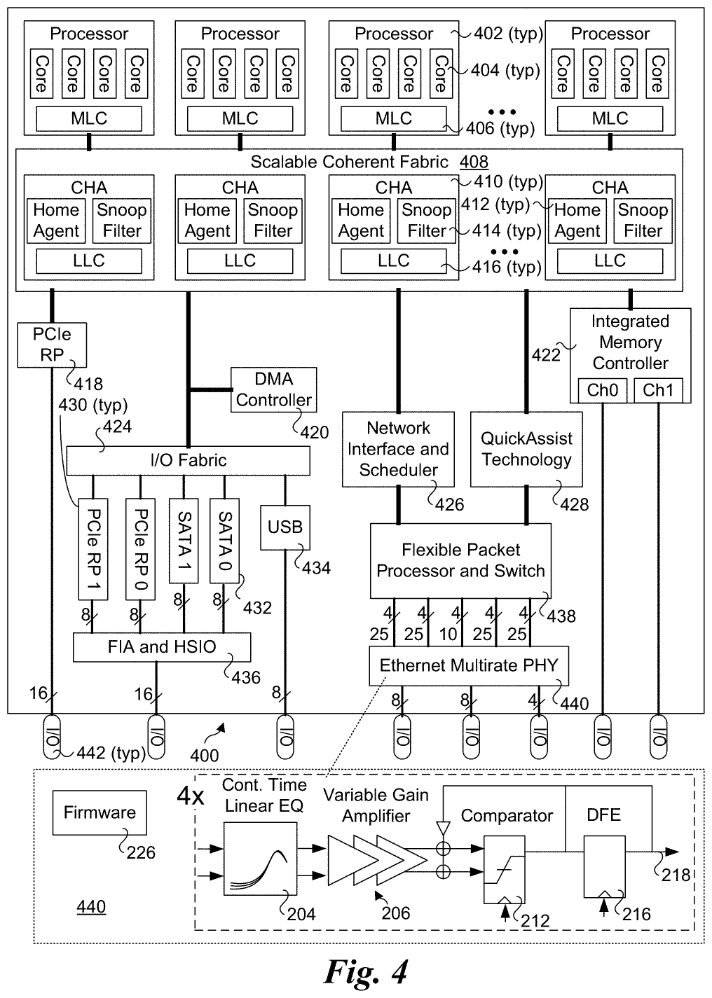

In some embodiments, the approach is implemented in an Ethernet PHY. The Ethernet PHY may be implemented in a stand-alone component, such as a NIC (Network Interface Controller) chip, or may be implemented as a circuit block in a System on a Chip (SoC). An example of an SoC 400 including an integrated Ethernet PHY is shown in FIG. 4.

SoC 400 includes multiple processors 402, each including a plurality of cores 404 and a Mid-Level Cache (MLC) 406. Processors 402 are coupled to a scalable coherent fabric 408 that includes multiple cache agents (CHAs) 410, each having a home agent 412, a snoop filter 414 and a Last-Level Cache (LLC) 416. In one embodiment each processor 402 is associated with a respective CHA 410. Other configuration may also be used, as will be recognized by those skilled in the art.

Various components are coupled to scalable coherent fabric 408 including a PCIe root port (RP) 418, a Direct Memory Access (DMA) controller 420, and an integrated memory controller 422 having one or more channels such as depicted by two channels Ch0 and Ch1. An Input/Output (I/O) fabric 424 is also connected to scalable coherent fabric 408, as is a network interface and scheduler 426 and an Intel® QuickAssist technology block 428.

Multiple I/O components are coupled to I/O fabric 424 including a pair of PCIe RPs 430, a pair of SATA (Serial ATA) controllers 432, and a USB (universal serial bus) block 434. PCIe RPs 430 and SATA controllers 432 are coupled to a Flexible I/O Adapter (FIA) and high-speed IO (HSIO) block 436, which is configurable to output various combinations of signals received from PCIe RPs 430, and SATA controllers 432.

Network interface and scheduler 426 and QuickAssist technology block 428 are coupled to a flexible packet processor and switch 438 that includes multiple 4-lane links coupled to an Ethernet multirate PHY 440. In the illustrated embodiment, there are four 25 Gigabits per second (25 G) and one 10 G link. However, this is merely exemplary and non-limiting, as other combinations of links may be used.

The various I/O components and interfaces are coupled to I/O pins or BGA balls 442 that are disposed beneath SoC 400. For example, SoC 400 may be packaged as a Pin Grid Array (PGA) in which case I/O pins are used or a Ball Grid Array (BGA) in which case solder balls are used. (It is further noted an SoC may be installed in a PGA or BGA chip carrier, as well).

In the Figures herein, a number above a slash, such as 8/represents the number of lanes for a given link. For single-ended signals there is an I/O pin or BGA ball for each lane (for multi-lane links) in each direction (2 wires per bi-directional lane or link). For differential signals there would be a pair of I/O pins or BGA balls for each lane, per each direction (4 wires per bi-directional lane). For an 8-lane link (four lanes each direction), there would be 16 I/O pins or BGA balls 442. Channels Ch0 and CH1 of integrated memory controller 422 also employ a multilane link or bus (not shown).

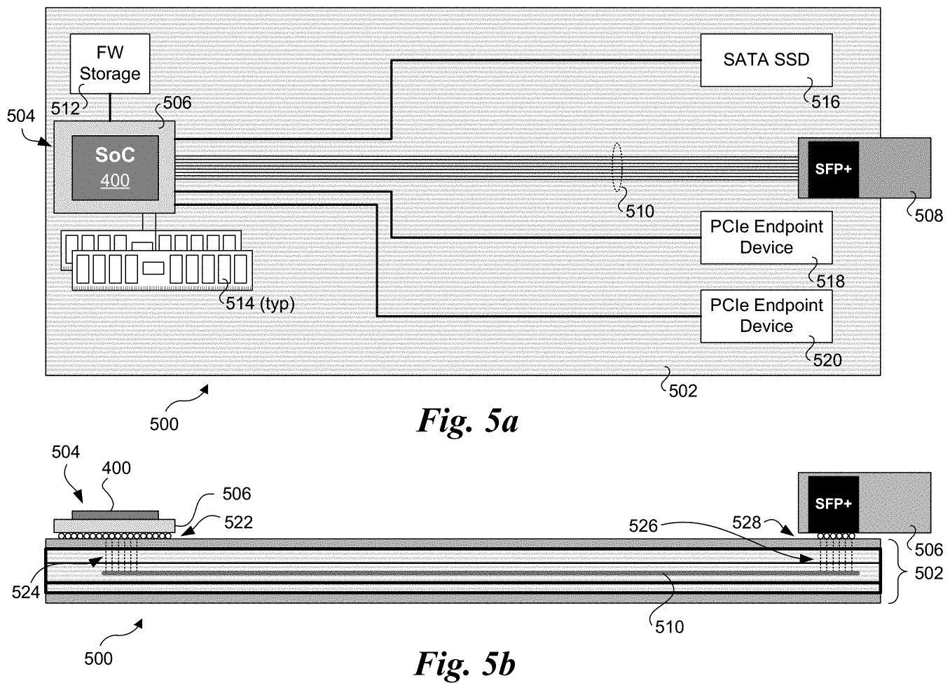

FIGS. 5a and 5b respectively show plan and cross-section views of a compute platform 500. The compute platform includes a multi-layer PCB 502 on which various components are mounted or otherwise operative coupled to. In this simplified example, the components include an SoC package 504 including an SoC 400 and an SoC BGA chip carrier 506, an SFP+ (small form factor pluggable optical) module 508, signal path traces 510, a firmware (FW) storage device 512, one or more DDR (double-data rate) DIMMs (Dual Inline Memory Modules) 514, a SATA solid-state drive (SSD) 516, and a pair of PCIe endpoint devices 518 and 520. As will be recognized by those skilled in the art, a compute platform would include multiple other components that are not shown for simplicity and clarity.

As shown in the cross-section view of FIG. 5b, the BGA chip carrier 506 of SoC package 504 is electronically coupled to a mating array of solder pads on a top layer of PCB 502 via solder balls 522. The signal path between SoC 400 and SFP+ module 506 is from SoC 400 to BGA chip carrier 506 to vias 524 in PCB 502 coupled to the BGA pads, through traces 510 in a routing layer in PCB 502, which are coupled at the opposing end to BGA pads 528 by means of vias 526. SPF+ module 506 may be mounted to PCB 508 using various means, such as but not limited to the BGA balls in FIG. 5b.

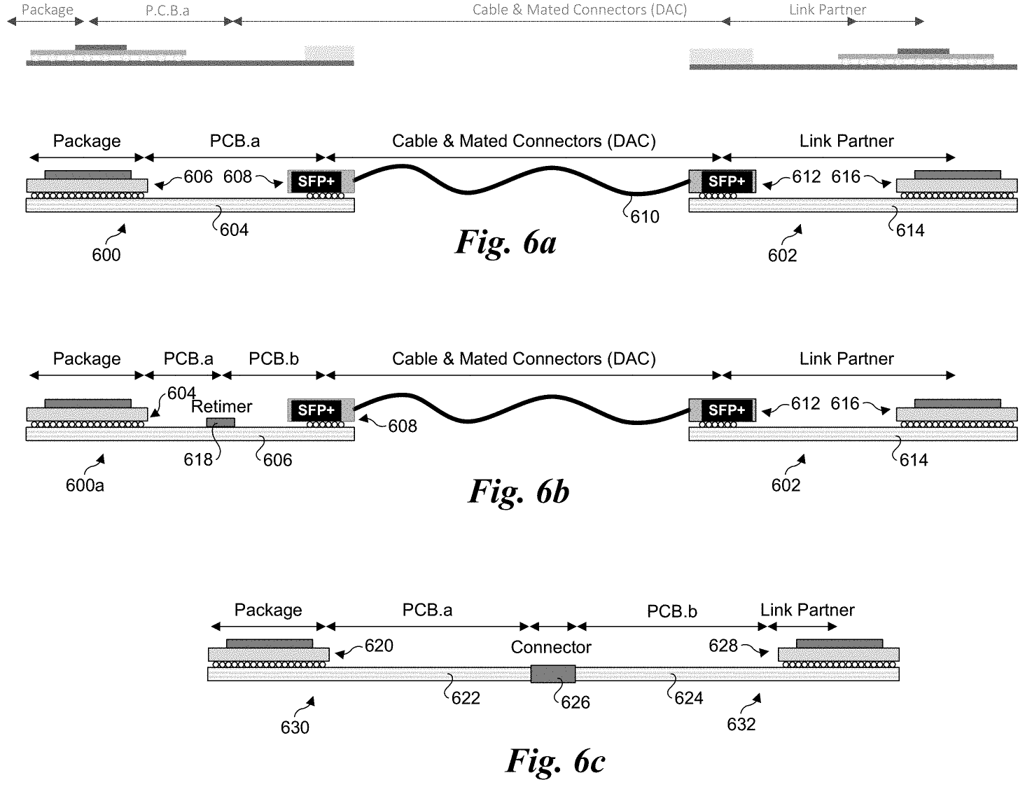

FIGS. 6a, 6b, and 6c depict end-to-end signal paths for which the continuous adaptive equalization approach may be applied. In FIG. 6a, communication is between a compute platform 600 and a compute platform 602 comprising link partners. Each of compute platforms 600 and 602 have similar configurations, where compute platform 600 includes an SoC package 604 mounted to a PCB 606 and communicatively coupled to an SFP+ module 608 using signal path traces and vias similar to the routing scheme shown in FIGS. 5a and 5b. Likewise, compute platform 602 includes an SFP+ module 612 mounted to a PCB 614 and communicatively coupled to an SoC package 616 using signal path traces and vias in PCB 614. SPF+ modules 608 and 612 are coupled to opposing ends of a cable 610.

As shown above the components, the signal path includes a PCB.a segment, a cable & mated connectors segment, and a link partner segment. Depending on the environment and where the compute platforms are located, the continuous adaptive equalization approach may be applied to the PCB.a segment, or it may be applied to the entire signal path or a portion of the signal path in addition to the PCB.a segment.

The configuration shown in FIG. 6b is similar to that shown in FIG. 6a, except a platform 600a includes a retimer 618 mounted to PCB 604. The compensated signal path segments for compute platform 600a are depicted as PCB.a and PCB.b.

Under the configuration shown in FIG. 6c, a first SoC package 620 is mounted to a first PCB 622 that is coupled to a second PCB 624 via a connector 626. A second SoC package 628 is mounted to PCB 624. In one embodiment, SoC package 620 and PCB 622 are part of a compute platform 630, while SoC package 628 and PCB 624 are part of a compute platform 632. For example, compute platforms 630 and 632 may be server blades or server modules that are coupled to a backplane connector, mid-plane connector, or similar type of connector in a blade server or the like. As shown, the signal path segments include PCB.a, the connector, and PCB.b signal. Under the configuration shown in FIG. 6c, both compute platforms 630 and 632 would be exposed to the same thermal environment (presuming both compute platforms are executing similar workloads).

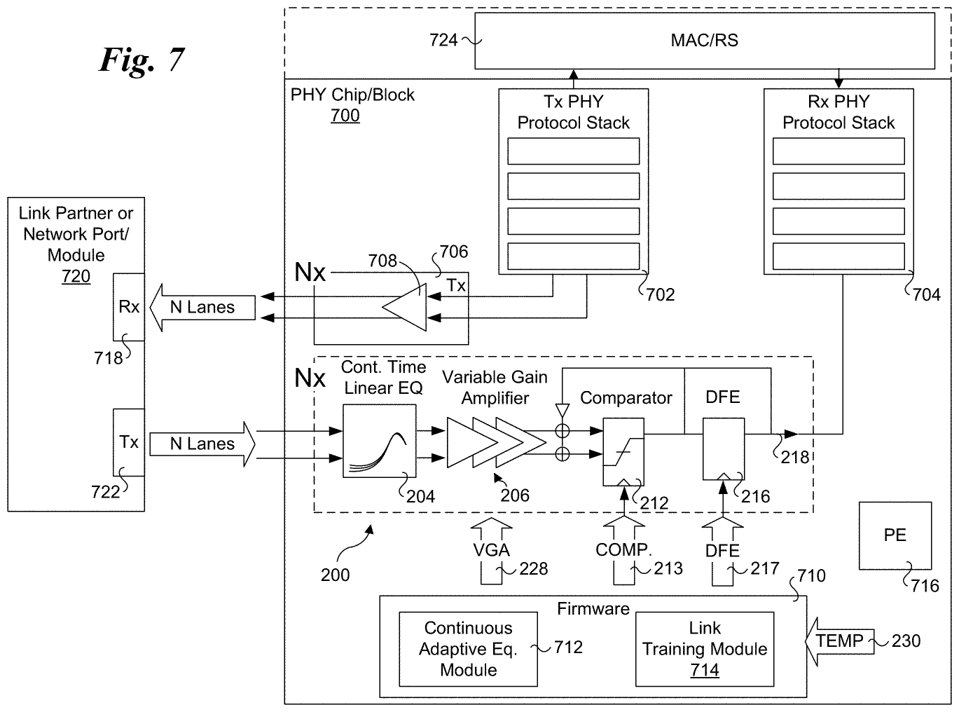

A genericized PHY chip/block 700 that is illustrative of the basic circuitry that may be used in a variety of different types of PHYs is shown in FIG. 7. As its name implies, PHY chip/block 700 may be a stand-alone PHY chip or a PHY circuit block within a chip or SoC providing additional functionality, such as in SoC 400, a NIC chip, or various I/O interfaces including but not limited to PCIe, CXL (Compute Express Link), and UPI (Ultra Path Interconnect), in addition to PHYs configured to support various high-speed Ethernet standards such as but not limited to 25GBASE-KR, 25GBASE-CR, 100GBASE-KR4, 50GBASE-KR, 50GBASE-CR, 200GBASE-CR4, 400GBASE-CR4, and 400GBASE-KR4. In addition, PHY chip/block 700 is illustrative of future high-speed PHYs including Gen 6 PCIe and CXL PHYs. PHY chip/block 700 may also be implemented in a Common Public Radio Interface (CPRI, used for base station to radios in cellular and similar), and an OIF-CEI (Optical Interconnect Forum, Common Electrical Interface) PHY.

PHY chip/block 700 includes a transmit (Tx) PHY protocol stack 702 and a receive (Rx) PHY protocol stack 704. These Tx and Rx PHY protocol stacks will have one or more layers and/or sublayers for implementing a Tx and Rx PHY corresponding to a given protocol. For example, a high-speed Ethernet link such as a 100GBase, 200GBase, or 400GBase link may have a particular set of layers including a Physical Coding Sublayer (PCS) sublayer, a Physical Media Attachment (PMA) sublayer, a Physical Media Dependent (PMD) sublayer, an AN (analog) sublayer, etc. Some protocols may further use a Forward Error Correction (FEC) sublayer. For protocols such as PCIe and CXL, different vendors may implement different SERDES (Serialize/Deserialize) schemes in addition to standardized PCIe and CXL layers/sublayers.

PHY chip/block 700 is configured to support a link with N lanes per direction, where N is an integer (e.g., 1, 2, 4, 8, 16, etc.) Each of the N lanes employs an instance of the same circuit, where one instance of the circuitry is depicted in FIG. 7. On the transmit side, the Tx circuitry is depicted as a Tx block 706 including an amplifier 708; in practice, the Tx circuitry will include various other circuit elements, as would be recognized by those skilled in the communication arts. The receive side includes N instances of receiver equalization components 200, as illustrated above in FIGS. 2 and 4. In addition, other circuitry may also be included in the receive path (not shown).

PHY chip/block 700 further includes firmware 710 comprising a continuous adaptive equalization module 712 and a link training module 714. In the illustrated example, continuous adaptive equalization module 712 and a link training module 714 comprise firmware instructions that are executed a processing element (PE) 716. Optionally, all or a portion of the logic for implementing continuous adaptive equalization and link training may be implemented via other forms of embedded logic, such as programmable logic (e.g., a field programmable gate array (FPGA)) and/or fixed logic (ASIC, DSP, etc.). For embodiments employing firmware instruction executed on some type of processing element, there will generally be one set of firmware instructions regardless of the number of lanes. At the same time, it is noted that separate instruction threads may be executed for each receive lane. For embedded logic employing programmable logic, there may generally be a set of programmable logic per instance of receive lane.

As further shown in FIG. 7, the N transmit lanes are coupled to an Rx port 718 on a link partner or network port/module 720. Meanwhile, a Tx port 722 on link partner or network port/module 720 is used to transmit signals over N lanes that are received and processed by respective instances of receiver equalization components 200. It is noted that when link partner or network port/module 720 is a network port or module (e.g., and SFP+ module), Rx port 718 and Tx port 722 may be illustrative of pass-through ports. Depending on the type of port/module, Rx port 718 and Tx port 722 may include some means for buffering, as well as other types of circuitry, such as signal conditioning/equalization circuitry, etc.

FIG. 7 further shows a MAC/Reconciliation Sublayer (RS) block 724. Under different protocols, this block implements the MAC (Media Access Control) layer. For protocols requiring a reconciliation sublayer, this block also implements this sublayer. In some embodiments, MAC/RS block 724 is implemented in a physical component that is separate from PHY chip/block 700. As shown by the dashed outline, in other embodiments, MAC/RS 724 is implemented on the same chip as PHY chip/block 700.

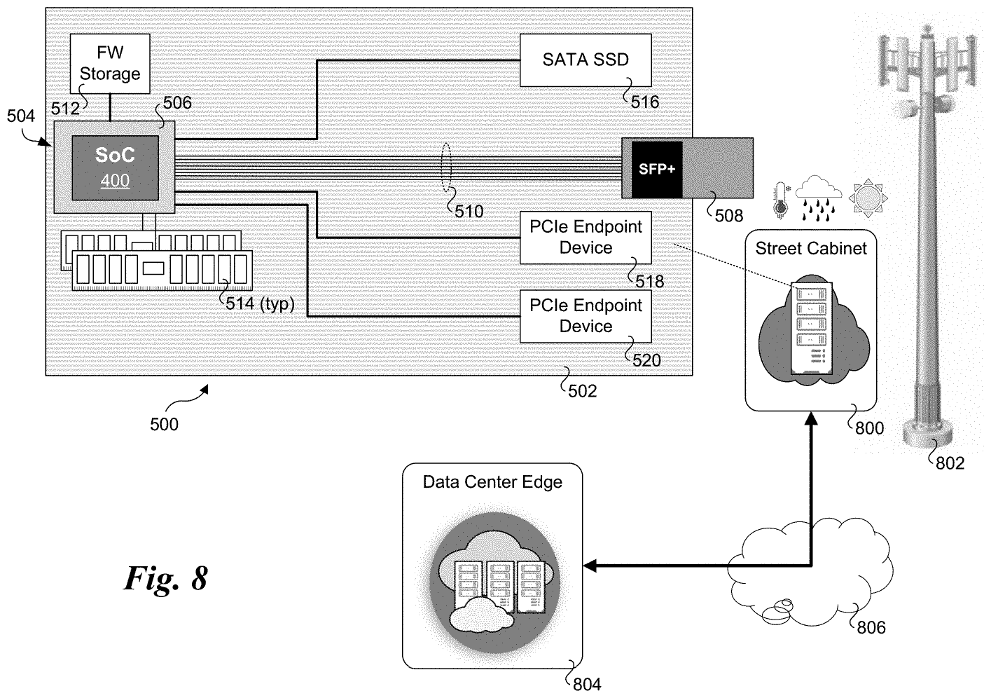

FIG. 8 illustrates a non-limiting example implementation of one or more compute platforms 500 in a street cabinet 800 located at the base of a cellular tower 802. The compute platforms in the street cabinet uses one or more high-speed Ethernet links to connect to one or more compute platforms in a data center edge 804 via a backhaul network 806.

As shown by the freezing and sun icons, the street cabinet is exposed to local weather conditions. Depending on the location, the temperature might range from −40° C. to 40° C. (−40° F. to 104° F.). In some locations, the high end of the temperature range might be even higher. Combine the external environment temperature conditions with heat generated by the one or more compute platforms in street cabinet 800, and the temperature range might extend up to 90° C.

Under a daily workload cycle, the workload might vary during the day, with low utilization at night. To accommodate for low utilization, the compute platforms(s) may be put into low-power states, such as by putting the SoC and/or its processors and other circuitry into a sleep state. Thus, overnight the temperature of PCB 502 might reach the ambient weather temperature. During high utilization, the compute platforms will generate heat that may raise the temperature within the street cabinet to much higher temperatures than the ambient weather temperature.

As a further consideration, a deployment in a telecom or other high-demand environment requiring 99.9999 uptime may necessitate that the platform and its links be operational for many years without being brought down. Thus, the temperature range while a given platform is operating (without being taken offline) could easily exceed 100° C.

Under the continuous adaptive equalization approach, equalization components in the receiver are adjusted to maintain adequate margins in view of increased or decreased insertion losses caused by temperature changes in the platform PCBs and (optionally) cabling. This approach enables the link to operate correctly (e.g., without bit errors) over wide temperature ranges.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As discussed above, various aspects of the embodiments herein may be facilitated by corresponding software and/or firmware components and applications, such as software and/or firmware executed by an embedded processor or the like. Thus, embodiments of this invention may be used as or to support a software program, software modules, firmware, and/or distributed software executed upon some form of processor, processing core or embedded logic a virtual machine running on a processor or core or otherwise implemented or realized upon or within a non-transitory computer-readable or machine-readable storage medium. A non-transitory computer-readable or machine-readable storage medium includes any mechanism for storing or transmitting information in a form readable by a machine (e.g., a computer). For example, a non-transitory computer-readable or machine-readable storage medium includes any mechanism that provides (e.g., stores and/or transmits) information in a form accessible by a computer or computing machine (e.g., computing device, electronic system, etc.), such as recordable/non-recordable media (e.g., read only memory (ROM), random access memory (RAM), magnetic disk storage media, optical storage media, flash memory devices, etc.). The content may be directly executable (“object” or “executable” form), source code, or difference code (“delta” or “patch” code). A non-transitory computer-readable or machine-readable storage medium may also include a storage or database from which content can be downloaded. The non-transitory computer-readable or machine-readable storage medium may also include a device or product having content stored thereon at a time of sale or delivery. Thus, delivering a device with stored content, or offering content for download over a communication medium may be understood as providing an article of manufacture comprising a non-transitory computer-readable or machine-readable storage medium with such content described herein.

The operations and functions performed by various components described herein may be implemented by firmware running on a processing element, via embedded hardware or the like, or any combination of hardware and software/firmware. Such components may be implemented as software/firmware modules, hardware modules, special-purpose hardware (e.g., application specific hardware, ASICs, DSPs, etc.), embedded controllers, hardwired circuitry, hardware logic, etc. Software content (e.g., data, instructions, configuration information, etc.) may be provided via an article of manufacture including non-transitory computer-readable or machine-readable storage medium, which provides content that represents instructions that can be executed. The content may result in a computer performing various functions/operations described herein.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. An apparatus configured to implement an interface for a link comprising an Input/Output (I/O) link or a communications link, comprising:
for one or more receive lanes in the link, a receiver Physical Layer (PHY) circuit block having a chain of equalizer components including a variable gain amplifier (VGA); and
embedded logic configured, for the receive lane, to,
set an initial VGA gain based on at least one temperature input;
perform link training during which one or more of the equalizer components are adjusted to obtain link convergence;
following link convergence, transition to a link up phase and begin receiving data; and
while operating in the link up phase, adjust one or more of the equalizer components in response to changes in insertion loss to maintain operation of the link within a link margin.

2. The apparatus of claim 1, wherein the chain of equalizer components includes the VGA and a Decision Feedback Equalizer (DFE), and wherein the one or more equalizer components that are adjusted in response to changes in insertion loss include the VGA and the DFE.

3. The apparatus of claim 1, wherein the chain of equalization components comprises a continuous time linear equalizer (CTLE), the VGA, and a Decision Feedback Equalizer (DFE).

4. The apparatus of claim 3, wherein a PHY receiver circuitry block includes a comparator, and wherein during link training the CTLE is configured to search for Clock and Data Rate (CDR) lock at the comparator.

5. The apparatus of claim 1, wherein the apparatus comprises an Ethernet PHY configured to support at least one Ethernet standard under which each of one or more lanes has a bandwidth of at least 25 Gigabits per second.

6. The apparatus of claim 1, wherein the apparatus comprises an Ethernet PHY, a Peripheral Component Interconnect Express (PCIe) PHY, a Compute Express Link (CXL) PHY, an Ultra Path Interconnect (UPI) PHY, a Common Public Radio Interface (CPRI) PHY, or an Optical Interconnect Forum, Common Electrical Interface (OIF-CEI) PHY.

7. The apparatus of claim 1, wherein the apparatus comprises a System on a Chip (SoC), and wherein the receiver PHY circuit block for each receive lane are part of an I/O link or communication link PHY block embedded on the SoC.

8. That apparatus of claim 1, wherein the apparatus comprises a chip configured to be electrically coupled to a printed circuit board (PCB) and the I/O link or communications link comprises signal traces in the PCB, and wherein the apparatus is configured to increase or attenuate signal gain to address changes in signal insertion loss due to changes in the PCB temperature.

9. That apparatus of claim 1, wherein the apparatus comprises a chip configured to be electrically coupled to a printed circuit board (PCB) and a first portion of the I/O link or communications link comprises signal traces in the PCB and a second portion of the I/O link comprises a cable, and wherein the apparatus is configured to increase or attenuate signal gain to address changes in signal insertion loss due to changes in the PCB temperature and the cable.

10. The apparatus of claim 1, wherein the at least one temperature input comprises a temperature of the apparatus, and the changes to the one or more temperature inputs include changes to the apparatus temperature.

11. A method implemented in a Physical layer (PHY) chip or block for an Input/Output (I/O) link or a communications link, the PHY chip or block including a receiver Physical Layer (PHY) circuit block for one or more receive lanes in the I/O link or communication link having a chain of equalizer components including a variable gain amplifier (VGA), the method comprising:
receiving an initial temperature input;
for a receive lane,
setting an initial VGA gain based on the initial temperature input;
performing link training during which one or more of the equalizer components are adjusted to obtain link convergence;
following link convergence, transitioning to a link up phase and begin receiving data; and
while operating in the link up phase, adjusting one or more of the equalizer components in response to changes in one or more temperature inputs to maintain operation of the link within a link margin.

12. The method of claim 11, wherein the chain of equalizer components includes the VGA and a Decision Feedback Equalizer (DFE), and wherein the one or more equalizer components that are adjusted in response to temperature changes include the VGA and the DFE.

13. The method of claim 11, wherein the chain of equalization components comprises a continuous time linear equalizer (CTLE), the VGA, and a Decision Feedback Equalizer (DFE), and wherein during link training the CTLE searches for Clock and Data Rate (CDR) lock at the comparator

14. The method of claim 11, wherein the I/O link or communications link comprises an Ethernet link in accordance with at least one Ethernet standard under which each of one or more lanes has a bandwidth of at least 25 Gigabits per second.

15. That method of claim 11 wherein the I/O link or communications link comprises signal traces in a printed circuit board (PCB), and wherein the method is implemented to increase or attenuate signal gain to address changes in signal insertion caused by changes in the PCB temperature.

16. The method of claim 11, wherein the I/O link or communications link comprises a first link segment comprising signal traces in a printed circuit board (PCB) and a second link segment comprising a cable, and wherein the method is implemented to increase or attenuate signal gain to address changes in signal insertion loss caused by changes in the temperature of the PCB and the cable.

17. A compute platform, comprising:
a printed circuit board (PCB)
a System on a Chip, electrically coupled to the PCB, including a one or more processors having a plurality of processor cores and a link interface including a Physical Layer (PHY) block;
one of a link partner component, a network port, or network module electrically coupled to the PCB; and
a link coupled between the PHY block and the link partner component, network port, or network module, the link comprising a plurality of traces formed in the PCB,
wherein the PHY block is configured to perform link training at an initial temperature and increase or attenuate signal gain for the link in response to changes in an input temperature measurement of the SoC or PCB to address changes in signal insertion loss caused by changes in the temperature of the PCB.

18. The compute platform of claim 17, wherein the PHY block comprises:
for each of one or more receive lanes in the link, a receiver Physical Layer (PHY) circuit block having a chain of equalizer components including a variable gain amplifier (VGA); and
embedded logic configured, for each receive lane, to,
set an initial VGA gain based on an initial temperature measurement;
perform link training during which one or more of the equalizer components are adjusted to obtain link convergence;
following link convergence, transition to a link up phase and begin receiving data; and
while operating in the link up phase, adjust one or more of the equalizer components in response to changes in one or more temperature inputs to maintain operation of the link within a link margin.

19. The compute platform of claim 18, wherein the chain of equalizer components includes the VGA and a Decision Feedback Equalizer (DFE), and wherein the one or more equalizer components that are adjusted in response to temperature changes include the VGA and the DFE.

20. The compute platform of claim 17, wherein the PHY block comprises an Ethernet PHY block configured to support at least one Ethernet standard under which each of one or more lanes has a bandwidth of at least 25 Gigabits per second.
